(19) United States
(12) Patent Application Publication
(10) Pub. No.: US 2023/0422576 A1
(43) Pub. Date: Dec. 28, 2023

(54) DISPLAY DEVICE

(71) Applicant: Japan Display Inc., Tokyo (JP)

(72) Inventor: Masakazu GUNJI, Tokyo (JP)

(73) Assignee: Japan Display Inc., Tokyo (JP)

(21) Appl. No.: 18/465,203

(22) Filed: Sep. 12, 2023

Related U.S. Application Data
(63) Continuation of application No. PCT/JP2022/009654, filed on Mar. 7, 2022.

(30) Foreign Application Priority Data
Mar. 12, 2021 (JP) 2021-040524

(51) Int. Cl. H10K 59/80; H10K 59/35

(52) U.S. Cl. CPC H10K 59/80515; H10K 59/35; H10K 59/80518; H10K 59/12

(57) ABSTRACT

According to one embodiment, a display device includes a base material, and a display area including a plurality of pixels arrayed in matrix in a first direction and a second direction. Each of the pixels includes a first subpixel, a second subpixel and a third subpixel. Each of the subpixels includes two overlap areas which overlap subpixels which are adjacent in the first direction, and an effective area which contributes display of images. In the first subpixel, neither of the two overlap areas is included in the effective area. In the second subpixel, one of the two overlap areas is included in the effective area, and the other one is not included in the effective area. In the third subpixel, both of the two overlap areas are included in the effective area.

### CROSS-REFERENCE TO RELATED APPLICATIONS

This application is a Continuation Application of PCT Application No. PCT/JP2022/009654, filed Mar. 7, 2022 and based upon and claiming the benefit of priority from Japanese Patent Application No. 2021-040524, filed Mar. 12, 2021, the entire contents of all of which are incorporated herein by reference.

### FIELD

Embodiments described herein relate generally to a display device.

### BACKGROUND

Recently, display devices to which an organic light emitting diode (OLED) is applied as a display element have been put into practical use. The display element comprises an organic layer between a pixel electrode and a common electrode. The organic layer includes functional layers such as a hole transport layer and an electron transport layer in addition to a light emitting layer.

While the practical use of display devices to which an organic light emitting diode is applied is advanced, these display devices have a problem in which high definition is difficult.

### BRIEF DESCRIPTION OF THE DRAWINGS

FIG. 1 is a diagram showing a configuration example of a display device according to an embodiment.

FIG. 2 is a plan view showing an example of the pixels shown in FIG. 1.

FIG. 3 is a cross-sectional view showing the section of a plurality of subpixels cut along the A-B line of FIG. 2.

FIG. 4A is a schematic pattern diagram for explaining the layer structure of a display element according to the embodiment.

FIG. 4B is a schematic pattern diagram for explaining an overlap area according to the embodiment.

FIG. 5A is a diagram for more specifically explaining the layers shown in FIG. 4A.

FIG. 5B is a diagram for more specifically explaining the layers shown in FIG. 4B.

FIG. 6 is a cross-sectional view showing the section of a subpixel comprising the configuration of a comparative example.

FIG. 7 is a cross-sectional view showing the section of subpixels comprising the configuration of a modified example.

FIG. 8 is a schematic pattern diagram for explaining an overlap area in the configuration of the modified example.

### DETAILED DESCRIPTION

In general, according to one embodiment, a display device includes a base material, and a display area including a plurality of pixels arrayed in matrix in a first direction and a second direction intersecting with the first direction. Each of the pixels includes a first subpixel including an organic layer having a first color, a second subpixel including an organic layer having a second color and a third subpixel including an organic layer having a third color. Each of the subpixels includes two overlap areas which overlap subpixels which are adjacent in the first direction, and an effective area which contributes display of images. In the first subpixel, neither of the two overlap areas is included in the effective area. In the second subpixel, one of the two overlap areas is included in the effective area, and the other one is not included in the effective area. In the third subpixel, both of the two overlap areas are included in the effective area.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the drawings show schematic illustration rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction or a first direction. A direction parallel to the Y-axis is referred to as a Y-direction or a second direction. A direction parallel to the Z-axis is referred to as a Z-direction or a third direction. The plane defined by the X-axis and the Y-axis is referred to as an X-Y plane. The plane defined by the X-axis and the Z-axis is referred to as an X-Z plane. When the X-Y plane is viewed, the appearance is defined as a plan view.

According to some embodiments, a display device DSP is an organic electroluminescent display device comprising an organic light emitting diode (OLED) as a display element, and is mounted on televisions, personal computers, mobile terminals, mobile phones and the like. It should be noted that the display element explained below can be applied as a light emitting element of an illumination device. The display device DSP can be also used for another electronic device such as an illumination device.

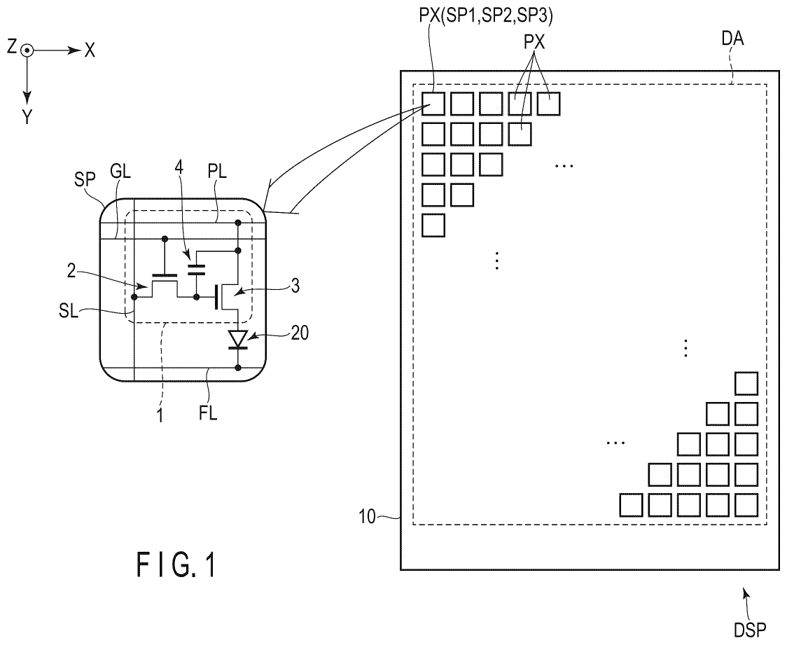

FIG. 1 is a diagram showing a configuration example of a display device DSP according to the present embodiment. The display device DSP comprises, on an insulating base material 10, a display area DA which displays an image. The base material 10 may be glass or a resinous film having flexibility.

The display area DA comprises a plurality of pixels PX arrayed in matrix in a first direction X and a second direction Y. Each pixel PX comprises a plurality of subpixels SP1, SP2 and SP3. For example, each pixel PX comprises a red subpixel SP1 (first subpixel), a green subpixel SP2 (second subpixel) and a blue subpixel SP3 (third subpixel). It should be noted that each pixel PX may comprise four or more subpixels. Specifically, in addition to the above three subpixels, each pixel PX may comprise a subpixel which exhibits another color, or more subpixels which exhibit other colors, such as white.

Now, this specification briefly explains a configuration example of a subpixel SP included in a pixel PX.

The subpixel SP comprises a pixel circuit 1, and a display element 20 in which driving is controlled by the pixel circuit 1. The pixel circuit 1 comprises a pixel switch 2, a drive transistor 3 and a capacitor 4. The pixel switch 2 and the drive transistor 3 are, for example, switch elements consisting of thin-film transistors (TFTs).

Regarding the pixel switch 2, a gate electrode is connected to a scanning line GL, and a source electrode is connected to a signal line SL, and a drain electrode is connected to one of the electrodes of the capacitor 4 and to the gate electrode of the drive transistor 3. Regarding the drive transistor 3, a source electrode is connected to the other electrode of the capacitor 4 and to a power line PL, and a drain electrode is connected to the anode of the display element 20. The cathode of the display element 20 is connected to a feed line FL. It should be noted that the configuration of the pixel circuit 1 is not limited to the example shown in the figure.

The display element 20 is an organic light emitting diode (OLED) which is a light emitting element. For example, subpixel SP1 comprises a display element which emits light corresponding to a red wavelength. Subpixel SP2 comprises a display element which emits light corresponding to a green wavelength. Subpixel SP3 comprises a display element which emits light corresponding to a blue wavelength. Multicolor display can be realized since each pixel PX comprises a plurality of subpixels SP1, SP2 and SP3 exhibiting different display colors.

It should be noted that the display elements of subpixels SP1, SP2 and SP3 may be configured to emit light exhibiting the same color. This configuration enables monochromatic display.

When the display element 20 of each of subpixels SP1, SP2 and SP3 is configured to emit white light, a color filter facing each display element 20 may be provided. For example, subpixel SP1 comprises a red color filter facing the display element 20. Subpixel SP2 comprises a green color filter facing the display element 20. Subpixel SP3 comprises a blue color filter facing the display element 20. By this configuration, multicolor display can be realized.

Alternatively, when the display element 20 of each of subpixels SP1, SP2 and SP3 is configured to emit ultraviolet light, multicolor display can be realized by providing a light conversion layer facing each display element 20.

The detailed configuration of the display element 20 is explained later.

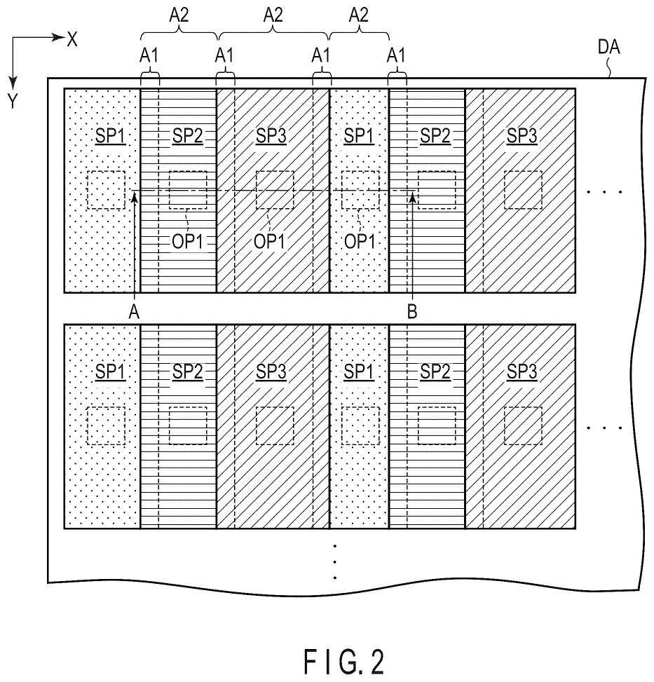

FIG. 2 is a plan view showing an example of the pixels PX shown in FIG. 1.

In the display area DA, each of subpixels SP1, SP2 and SP3 which constitute each pixel PX is formed into substantially a rectangular shape extending in the second direction Y, and subpixels SP1, SP2 and SP3 are arranged in the first direction X.

Each of subpixels SP1, SP2 and SP3 includes an overlap area A1 which overlaps a subpixel SP which is adjacent in the first direction X, and an effective area A2 which contributes to the display of images. In the present embodiment, the expression “to contribute to the display of images” means that the light emitted from the display element 20 can be extracted to the outside.

Subpixel SP1 is located on the lower side relative to subpixel SP2 in the overlap area A1 overlapping subpixel SP2, and is located on the lower side relative to subpixel SP3 in the other overlap area A1 overlapping subpixel SP3. As described in detail later, in each overlap area A1, of the light emitted from two overlapping subpixels SP, the light emitted from the subpixel SP located on the lower side is reflected by the configuration of the subpixel SP located on the upper side and is not extracted as light which contributes to the display of images. Thus, the two overlap areas A1 are not included in the effective area A2 of subpixel SP1.

Subpixel SP2 is located on the upper side relative to subpixel SP1 in the overlap area A1 overlapping subpixel SP1 and is located on the lower side relative to subpixel SP3 in the other overlap area A1 overlapping subpixel SP3. Thus, the effective area A2 of subpixel SP2 includes the overlap area A1 overlapping subpixel SP1 and does not include the other overlap area A1 overlapping subpixel SP3.

Subpixel SP3 is located on the upper side relative to subpixel SP1 in the overlap area A1 overlapping subpixel SP1 and is located on the upper side relative to subpixel SP2 in the other overlap area A1 overlapping subpixel SP2. Thus, the effective area A2 of subpixel SP3 includes two overlap areas A1.

As described above, the effective areas A2 of subpixels SP1, SP2 and SP3 have different areas, and the sizes of the effective areas A2 are decreased in the order of subpixels SP3, SP2 and SP1. By making the effective area A2 of subpixel SP3 larger than the effective areas A2 of subpixels SP1 and SP2, blue light which generally has a less luminous efficiency than red light and green light can be extracted more. To extract blue light which has a less luminous efficiency more, subpixel SP3 (the area on the X-Y plane) itself should be preferably formed so as to be larger than subpixels SP1 and SP2.

The display elements 20 included in subpixels SP1, SP2 and SP3 are connected to the pixel circuits 1 included in subpixels SP1, SP2 and SP3 through apertures OP1. Each aperture OP1 should be preferably formed such that the center of subpixel SP1, SP2 or SP3 is coincident with the center of the aperture OP1. By this configuration, the light emission areas of the display elements 20 can be provided so as to spread from the centers of subpixels SP1, SP2 and SP3. It should be noted that the size of each aperture OP1 (the area in the X-Y plane) is not limited to the size shown in the figure and may be an arbitrary size such as substantially the same size as the display element 20.

In the example of FIG. 2, subpixels SP1, SP2 and SP3 are rectangular. However, the shape of subpixel SP1, SP2 or SP3 is not limited to this example. For example, each of subpixels SP1, SP2 and SP2 may have an arbitrary shape different from a rectangular shape such as an arbitrary polygonal shape, a circular shape or an irregular shape. Subpixels SP1, SP2 and SP3 may have shapes different from each other.

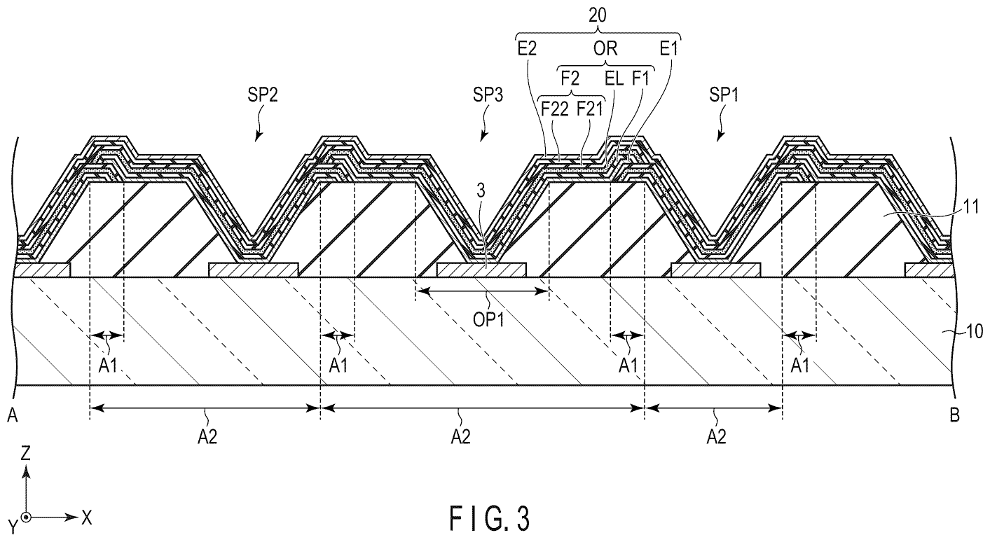

FIG. 3 is a cross-sectional view showing the section of a plurality of subpixels SP cut along the A-B line of FIG. 2. It should be noted that the configurations of subpixels SP1, SP2 and SP3 shown in FIG. 3 are the same as each other except that the emission colors of light emitting layers described later are different from each other. Thus, in the following description, firstly, the configuration of a subpixel SP is explained as an example.

The pixel circuit 1 shown in FIG. 1 is provided on the base material 10 and is covered with an insulating layer 11. FIG. 3 shows only the drive transistor 3 included in the pixel circuit 1 in a simplified manner. The insulating layer 11 corresponds to the underlayer of the display element 20 and is formed of, for example, an insulating material such as polyimide, acrylic resin, silicon nitride (SiN) or silicon oxide (SiO).

The display element 20 comprises a bottom electrode E1, an organic layer OR and a top electrode E2. The organic layer OR is provided so as to be interposed between the bottom electrode E1 and the top electrode E2.

The bottom electrode E1 is an electrode provided for each subpixel or each display element and is electrically connected to the drive transistor 3. This bottom electrode E1 may be called a pixel electrode, a reflective electrode, an anode, etc.

The top electrode E2 is an electrode provided over a plurality of subpixels or a plurality of display elements and is electrically connected to the feed line FL. This top electrode E2 may be called a common electrode, a counter-electrode, a cathode, etc.

The bottom electrode E1 is provided on the insulating layer 11 and is connected to the drive transistor 3 through the aperture OP1 formed in the insulating layer 11. The aperture OP1 is formed in an area overlapping the drive transistor 3 and is a through-hole which penetrates the insulating layer 11 such that the drive transistor 3 is exposed from the insulating layer 11.

The bottom electrode E1 is a transparent electrode formed of, for example, a transparent conductive material such as indium tin oxide (ITO) or indium zinc oxide (IZO). It should be noted that the bottom electrode E1 may be a metal electrode formed of a metal material such as silver (Ag), aluminum (Al), titanium (Ti), molybdenum (Mo) or tungsten (W). Alternatively, the bottom electrode E1 may be a stacked layer body of a transparent electrode and a metal electrode. For example, the bottom electrode E1 may consist of a stacked layer body formed by stacking a transparent electrode, a metal electrode and a transparent electrode in order, or may consist of a stacked layer body of three or more layers.

The organic layer OR includes a first functional layer F1, a light emitting layer EL and a second functional layer F2. The second functional layer F2 further includes a unique functional layer F21 provided for each subpixel or each display element, and a common functional layer F22 provided over a plurality of subpixels or a plurality of display elements. The first functional layer F1, the light emitting layer EL, the unique functional layer F21 and the common functional layer F22 are stacked in this order from the bottom electrode E1 side.

The first functional layer F1 is provided between the bottom electrode E1 and the light emitting layer EL.

The light emitting layer EL is provided between the first functional layer F1 and the unique functional layer F21. The light emitting layer EL emits red light, green light or blue light.

The unique functional layer F21 is provided between the light emitting layer EL and the common functional layer F22.

The common functional layer F22 is provided between the unique functional layer F21 and the top electrode E2.

As described in detail later, each of the first functional layer F1 and the unique functional layer F21 and common functional layer F22 included in the second functional layer F2 is not limited to a single-layer body and may be a stacked layer body in which a plurality of layers are stacked. In this case, the layers are formed so as to be smaller as the layers are located on the lower side. A layer located on the lower side may be covered with an upper layer located on the upper side of the lower layer. The functional layers included in each of the first functional layer F1, the unique functional layer F21 and the common functional layer F22 may be partly omitted.

The top electrode E2 covers the organic layer OR. The top electrode E2 is a common layer which is used so as to be common to a plurality of subpixels or a plurality of display elements. The top electrode E2 is, for example, a transparent electrode formed of a transparent conductive material such as ITO or IZO. It should be noted that the top electrode E2 may be a semitransparent metal electrode formed of a metal material such as magnesium (Mg), silver (Ag) or aluminum (Al). The top electrode E2 is electrically connected to a feed line FL provided in the display area DA or a feed line FL provided outside the display area DA.

When the potential of the bottom electrode E1 is relatively higher than that of the top electrode E2, the bottom electrode E1 corresponds to an anode, and the top electrode E2 corresponds to a cathode. When the potential of the top electrode E2 is relatively higher than that of the bottom electrode E1, the top electrode E2 corresponds to an anode, and the bottom electrode E1 corresponds to a cathode.

In the present embodiment, as an example, this specification assumes a case where the bottom electrode E1 corresponds to an anode and the top electrode E2 corresponds to a cathode.

In the configuration shown in FIG. 3, the light emission area of the display element 20 can be formed in the portion of the organic layer OR provided between the bottom electrode E1 provided in the aperture OP1 and the top electrode E2 provided as a common layer.

In the configuration of the present embodiment shown in FIG. 3, each of subpixels SP1, SP2 and SP3 comprises the overlap areas A1 overlapping the adjacent subpixels SP. Subpixel SP1 is provided on the lower side relative to the adjacent subpixels SP2 and SP3 in the two overlap areas A1 located in the both end portions. In this configuration, of the light emitted from subpixel SP1, the light emitted from the overlap areas A1 is reflected on the bottom electrodes E1 of subpixels SP2 and SP3 located on the upper side and is not extracted to the outside as light which contributes to the display of images. Thus, the effective area A2 of subpixel SP1 corresponds to an area obtained by excluding the two overlap areas A1 from the light emission area of subpixel SP1.

Subpixel SP2 is located on the upper side relative to subpixel SP1 in, of the two overlap areas A1 located in the both end portions, the overlap area A1 overlapping subpixel SP1. To the contrary, subpixel SP2 is located on the lower side relative to subpixel SP3 in, of the two overlap areas A1 located in the both end portions, the overlap area A1 overlapping subpixel SP3. In this configuration, of the light emitted from subpixel SP2, the light emitted from the overlap area A1 overlapping subpixel SP3 is reflected on the bottom electrode E1 of subpixel SP3 located on the upper side and is not extracted to the outside as light which contributes to the display of images. Thus, the effective area A2 of subpixel SP2 corresponds to an area obtained by excluding the overlap area A1 overlapping subpixel SP3 from the light emission area of subpixel SP2.

Subpixel SP3 is provided on the upper side relative to the adjacent subpixels SP1 and SP2 in the two overlap areas A1 located in the both end portions. In this configuration, as no subpixel SP is located on the upper side of subpixel SP3, all of the light emitted from subpixel SP3 is extracted to the outside as light which contributes to the display of images. Thus, the effective area A2 of subpixel SP3 corresponds to the light emission area of subpixel SP3.

In the configuration shown in FIG. 3, the peripheral portion (end portion) of the bottom electrode E1 of each of subpixels SP1, SP2 and SP3 is covered with the organic layer OR. This configuration can prevent a short circuit caused by the contact between the bottom electrode E1 and the top electrode E2.

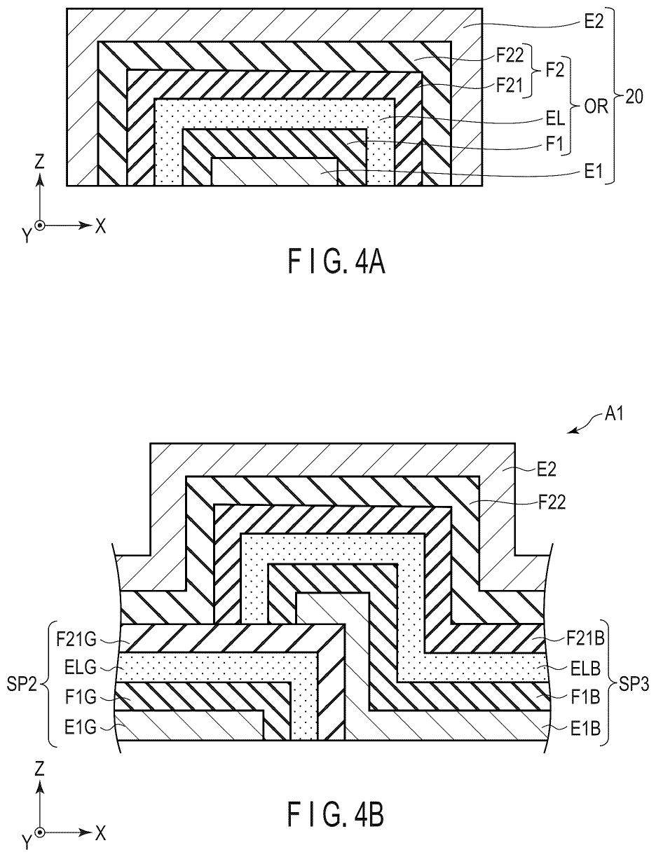

FIG. 4A is a schematic pattern diagram for explaining the layer structure of the display element 20. As described above, the display element 20 comprises the structure in which the bottom electrode E1, the first functional layer F1, the light emitting layer EL, the unique functional layer F21 included in the second functional layer F2, the common functional layer F22 included in the second functional layer F2 and the top electrode E2 are stacked in this order from the bottom electrode E1 side.

The first functional layer F1 covers the peripheral portion of the bottom electrode E1. The light emitting layer EL covers the peripheral portion of the first functional layer F1. The unique functional layer F21 covers the peripheral portion of the light emitting layer EL. The common functional layer F22 covers the peripheral portion of the unique functional layer F21. The top electrode E2 covers the peripheral portion of the common functional layer F22. In this manner, each of the layers included in the display element 20 is stacked so as to cover the peripheral portion of the lower layer which is adjacent in a third direction Z.

FIG. 4B is a schematic pattern diagram for explaining the overlap area A1. In the overlap area A1 shown in FIG. 4B, two subpixels SP2 and SP3 which are adjacent to each other are provided so as to overlap each other, and subpixel SP3 is located on the upper side relative to subpixel SP2. In the following explanation, “G” is added to the end of the reference number of each element corresponding to subpixel SP2, and “B” is added to the end of the reference number of each element corresponding to subpixel SP3.

As shown in FIG. 4A, the display element 20 constituting each of subpixels SP2 and SP3 comprises the structure in which the bottom electrode E1, the first functional layer F1, the light emitting layer EL, the unique functional layer F21, the common functional layer F22 and the top electrode E2 are stacked in this order from the bottom electrode E1 side.

In the overlap area A1, the peripheral portion of the bottom electrode E1G of subpixel SP2 is covered with the first functional layer F1G provided on the bottom electrode. In the overlap area A1, the peripheral portion of the first functional layer F1G is covered with the light emitting layer ELG provided on the first functional layer. In the overlap area A1, the peripheral portion of the light emitting layer ELG is covered with the unique functional layer F21G provided on the light emitting layer. In the overlap area A1, subpixel SP3 is provided on the unique functional layer F21G, and the peripheral portion of the unique functional layer is covered with the bottom electrode E1B of subpixel SP3.

In the overlap area A1, the bottom electrode E1B of subpixel SP3 is provided on the unique functional layer F21G of subpixel SP2. Since the bottom electrode E1B is provided to extend to a position overlapping the light emitting layer ELG of subpixel SP2, the light emitted from the light emitting layer ELG in the overlap area A1 is reflected on the bottom electrode E1B and is not extracted to the outside as light which contributes to the display of images. This configuration can prevent a color mixture which could be caused by the mixture of the light emitted from the light emitting layer ELG and the light emitted from the light emitting layer ELB.

In the overlap area A1, the peripheral portion of the bottom electrode EIB is covered with the first functional layer F1B provided on the bottom electrode. In the overlap area A1, the peripheral portion of the first functional layer F1B is covered with the light emitting layer ELB provided on the first functional layer. The peripheral portion of the first functional layer F1B is in contact with the unique functional layer F21G of subpixel SP2. In the overlap area A1, the peripheral portion of the light emitting layer ELB is covered with the unique functional layer F21B provided on the light emitting layer. The peripheral portion of the light emitting layer ELB is in contact with the unique functional layer F21G of subpixel SP2. In the overlap area A1, the peripheral portion of the unique functional layer F21B is covered with the common functional layer F22 provided on the unique functional layer. The peripheral portion of the unique functional layer F21B is in contact with the unique functional layer F21G of subpixel SP2.

In the overlap area A1, the common functional layer F22 which is a common layer is provided on the unique functional layer F21G of subpixel SP2 and the unique functional layer F21B of subpixel SP3. In the overlap area A1, the top electrode E2 which is a common layer is provided on the common functional layer F22.

As described above, at least the first functional layer F1G, the light emitting layer ELG, the unique functional layer F21G and the common functional layer F22 are interposed between the bottom electrode E1G of subpixel SP2 and the top electrode E2. Further, the peripheral portion of the bottom electrode E1G is covered with at least one of these layers. Thus, it is possible to prevent a short circuit caused by the contact between the bottom electrode E1G and the top electrode E2. Similarly, at least the first functional layer F1B, the light emitting layer ELB, the unique functional layer F21B and the common functional layer F22 are interposed between the bottom electrode E1B of subpixel SP3 and the top electrode E2. Further, the peripheral portion of the bottom electrode E1B is covered with at least one of these layers. Thus, it is possible to prevent a short circuit caused by the contact between the bottom electrode E1B and the top electrode E2.

Here, the overlap area A1 in which subpixels SP2 and SP3 overlap each other is explained. However, the overlap area A1 in which subpixels SP1 and SP2 overlap each other can be explained in a similar manner by replacing subpixel SP3 by subpixel SP2, replacing subpixel SP2 by subpixel SP1 and replacing the last reference symbols by the reference symbols of corresponding colors. Moreover, the overlap area A1 in which subpixels SP1 and SP3 overlap each other can be explained in a similar manner by replacing subpixel SP2 by subpixel SP1 and replacing the last reference symbol by the symbol of a corresponding color.

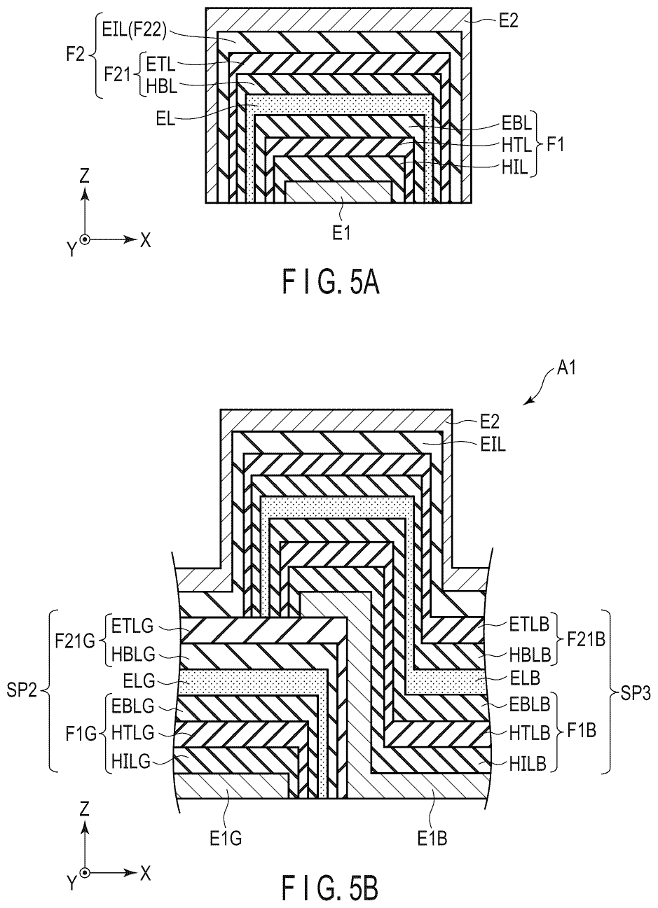

FIG. 5A is a diagram for more specifically explaining the layers included in the first functional layer F1 and the layers included in the second functional layer F2 shown in FIG. 4A.

The present embodiment assumes a case where the bottom electrode E1 corresponds to an anode, and the top electrode E2 corresponds to a cathode. Therefore, the first functional layer F1 comprises a structure in which a hole injection layer HIL, a hole transport layer HTL and an electron blocking layer EBL are stacked in this order from the bottom electrode E1 side. The second functional layer F2 comprises a structure in which an electron injection layer EIL, an electron transport layer ETL and a hole blocking layer HBL are stacked in this order from the top electrode E2 side. The unique functional layer F21 of the second functional layer F2 includes the electron transport layer ETL and the hole blocking layer HBL, and the common functional layer F22 of the second functional layer F2 includes the electron injection layer EIL.

Regarding the first functional layer F1, the hole injection layer HIL covers the peripheral portion of the bottom electrode E1, and the hole transport layer HTL covers the peripheral portion of the hole injection layer HIL, and the electron blocking layer EBL covers the peripheral portion of the hole transport layer HTL.

The light emitting layer EL covers the peripheral portion of the electron blocking layer EBL.

Regarding the unique functional layer F21, the hole blocking layer HBL covers the peripheral portion of the light emitting layer EL, and the electron transport layer ETL covers the peripheral portion of the hole blocking layer HBL. Regarding the common functional layer F22, the electron injection layer EIL covers the peripheral portion of the electron transport layer ETL. It should be noted that the top electrode E2 which is a common layer covers the peripheral portion of the electron injection layer EIL.

FIG. 5B is a diagram for more specifically explaining the layers included in the first functional layer F1 and the layers included in the second functional layer F2 shown in FIG. 4B. In the following explanation, similarly to the case of FIG. 4B, “G” is added to the end of the reference number of each element corresponding to subpixel SP2, and “B” is added to the end of the reference number of each element corresponding to subpixel SP3.

As shown in FIG. 5A, each of subpixels SP2 and SP3 comprises the structure in which the bottom electrode E1, the hole injection layer HIL, the hole transport layer HTL, the electron blocking layer EBL, the light emitting layer EL, the hole blocking layer HBL, the electron transport layer ETL, the electron injection layer EIL and the top electrode E2 are stacked in this order from the bottom electrode E1 side.

In the overlap area A1, the peripheral portion of the bottom electrode E1G of subpixel SP2 is covered with the hole injection layer HILG provided on the bottom electrode and included in the first functional layer F1G. In the overlap area A1, the peripheral portion of the hole injection layer HILG is covered with the hole transport layer HTLG provided on the hole injection layer and included in the first functional layer F1G. In the overlap area A1, the peripheral portion of the hole transport layer HTLG is covered with the electron blocking layer EBLG provided on the hole transport layer and included in the first functional layer F1G. In the overlap area A1, the peripheral portion of the electron blocking layer EBLG is covered with the light emitting layer ELG provided on the electron blocking layer.

In the overlap area A1, the peripheral portion of the light emitting layer ELG of subpixel SP2 is covered with the hole blocking layer HBLG provided on the light emitting layer and included in the unique functional layer F21G. In the overlap area A1, the peripheral portion of the hole blocking layer HBLG is covered with the electron transport layer ETLG provided on the hole blocking layer and included in the unique functional layer F21G. In the overlap area A1, subpixel SP3 is provided on the electron transport layer ETLG, and the peripheral portion of the electron transport layer is covered with the bottom electrode E1B of subpixel SP3.

In the overlap area A1, the bottom electrode E1B of subpixel SP3 is provided on the electron transport layer ETLG of subpixel SP2. The hole blocking layer HBLG included in the second functional layer F2G of subpixel SP2 is provided between the bottom electrode E1B of subpixel SP3 and the light emitting layer ELG of subpixel SP2. In this manner, carrier blocking layers such as the hole blocking layer HBL and the electron blocking layer EBL should be preferably provided between the bottom electrode of the subpixel SP provided on the upper side and the light emitting layer EL of the subpixel SP provided on the lower side in the overlap area A1. This configuration can prevent one of the subpixels SP from emitting light in response to the light emission of the other subpixel SP.

In the overlap area A1, the peripheral portion of the bottom electrode E1B is covered with the hole injection layer HILB provided on the bottom electrode and included in the first functional layer F1B.

In the overlap area A1, the peripheral portion of the hole injection layer HILB is covered with the hole transport layer HTLB provided on the hole injection layer and included in the first functional layer F1B. The peripheral portion of the hole injection layer HILB is in contact with the electron transport layer ETLG of subpixel SP2. In the overlap area A1, the peripheral portion of the hole transport layer HTLB is covered with the electron blocking layer EBLB provided on the hole transport layer and included in the first functional layer F1B. The peripheral portion of the hole transport layer HTLB is in contact with the electron transport layer ETLG of subpixel SP2. In the overlap area A1, the peripheral portion of the electron blocking layer EBLB is covered with the light emitting layer ELB provided on the electron blocking layer. The peripheral portion of the electron blocking layer EBLB is in contact with the electron transport layer ETLG of subpixel SP2.

In the overlap area A1, the peripheral portion of the light emitting layer ELB of subpixel SP3 is covered with the hole blocking layer HBLB provided on the light emitting layer and included in the unique functional layer F21B. The peripheral portion of the light emitting layer ELB is in contact with the electron transport layer ETLG of subpixel SP2. In the overlap area A1, the peripheral portion of the hole blocking layer HBLB is covered with the electron transport layer ETLB provided on the hole blocking layer and included in the unique functional layer F21B. The peripheral portion of the hole blocking layer HBLB is in contact with the electron transport layer ETLG of subpixel SP2. In the overlap area A1, the peripheral portion of the electron transport layer ETLB is covered with the electron injection layer EIL which is provided on the electron transport layer and which is the common functional layer F22. The peripheral portion of the electron transport layer ETLB is in contact with the electron transport layer ETLG of subpixel SP2.

In the overlap area A1, the electron injection layer EIL which is the common functional layer F22 is provided on the electron transport layer ETLG of subpixel SP2 and the electron transport layer ETLB of subpixel SP3. In the overlap area A1, the top electrode E2 which is a common layer is provided on the electron injection layer EIL.

As described above, the hole injection layer HILG, the hole transport layer HTLG, the electron blocking layer EBLG, the light emitting layer ELG, the hole blocking layer HBLG, the electron transport layer ETLG and the electron injection layer EIL are interposed between the bottom electrode E1G of subpixel SP2 and the top electrode E2. Further, the peripheral portion of the bottom electrode E1G is covered with at least one of these layers. Thus, it is possible to prevent a short circuit caused by the contact between the bottom electrode E1G and the top electrode E2. Similarly, the hole injection layer HILB, the hole transport layer HTLB, the electron blocking layer EBLB, the light emitting layer ELB, the hole blocking layer HBLB, the electron transport layer ETLB and the electron injection layer EIL are interposed between the bottom electrode E1B of subpixel SP3 and the top electrode E2. Further, the peripheral portion of the bottom electrode E1B is covered with at least one of these layers. Thus, it is possible to prevent a short circuit caused by the contact between the bottom electrode EIB and the top electrode E2.

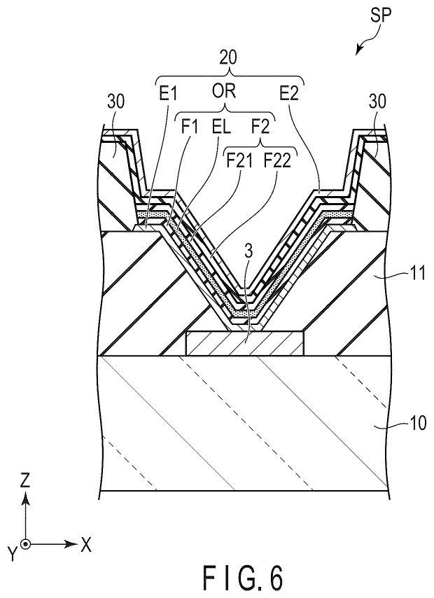

Here, the effects of the present embodiment are explained using the comparative example shown in FIG. 6. The comparative example is shown for explaining part of the effects which could be obtained from the present embodiment and does not exclude the effects common to the comparative example and the present embodiment from the scope of the present invention.

The configuration of the comparative example is different from that of the present embodiment in respect that a partition 30 is provided between adjacent subpixels SP. The partition 30 is provided on the insulating layer 11 and covers the peripheral portion of the bottom electrode E1. In the configuration of the comparative example, a short circuit caused by the contact between the bottom electrode E1 and the top electrode E2 is prevented by covering the peripheral portion of the bottom electrode E1 with the partition 30.

However, in the case of the configuration of the comparative example, as the partition 30 is provided, the light emission area (the area of light emission) of the display element 20 is narrowed. Moreover, in the case of the configuration of the comparative example, the area of the portion in which the partition 30 is provided is increased with increasing definition. As a result, the light emission area of the display element 20 is narrowed, and thus, high definition is difficult.

In the configuration of the present embodiment, each of subpixels SP1, SP2 and SP3 constituting each pixel PX is provided so as to overlap a subpixel SP which is adjacent in the first direction X, and further, the peripheral portion of the bottom electrode E1 included in each subpixel SP is covered with the organic layer OR included in the subpixel SP. In this configuration, even if the partition 30 for covering the peripheral portion of the bottom electrode E1 is not provided, the contact between the bottom electrode E1 and the top electrode E2 can be prevented. As the partition 30 is not provided, the light emission area can be extended.

In the configuration of the present embodiment, as described above, each of subpixels SP1, SP2 and SP3 constituting each pixel PX is provided so as to overlap a subpixel SP which is adjacent in the first direction X. Therefore, there is no need to provide the partition 30, and further, for example, a line or space for separating subpixels SP from each other is not needed between the subpixels SP. Thus, the light emission area can be extended.

Moreover, as there is no need to provide the partition 30 in the configuration of the present embodiment as described above, the reduction in the light emission area in connection with high definition can be prevented.

In the following description, a modified example of the configuration of the present embodiment is explained. In the following description, mainly, differences from the configuration shown in FIG. 3 and FIG. 5B are explained, and the explanation of the same configuration as FIG. 3 and FIG. 5B is omitted.

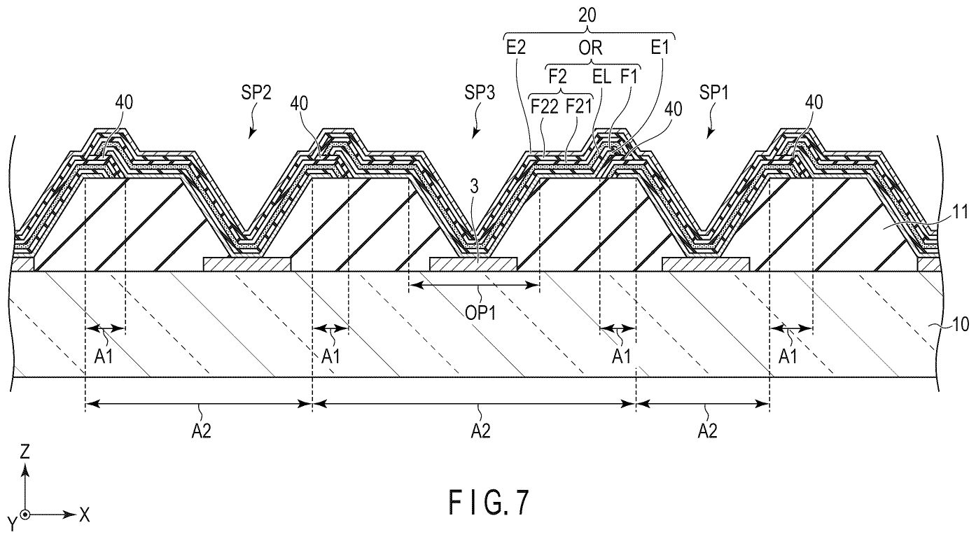

FIG. 7 is a cross-sectional view for explaining the configuration of a modified example of the present embodiment. The configuration of the modified example is different from the configuration shown in FIG. 3 in respect that a protective layer 40 is further provided between the subpixel SP provided on the lower side and the subpixel SP provided on the upper side in the overlap area A1.

The protective layer 40 is, for example, an insulating layer formed of an insulating material such as silicon nitride (SiN), silicon oxide (SiO) or lithium fluoride (LiF), or a carrier blocking layer such as a hole blocking layer or an electron blocking layer.

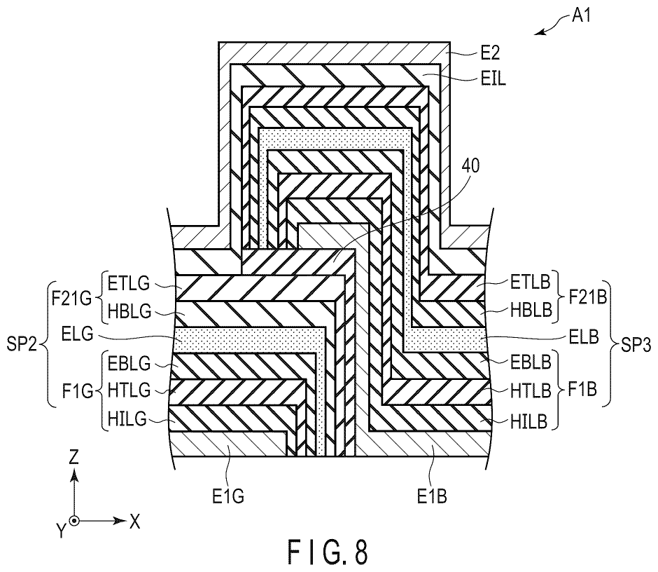

FIG. 8 is a diagram for explaining the overlap area A1 in the configuration of the modified example of the present embodiment. As shown in FIG. 8, in the overlap area A1, the peripheral portion of the electron transport layer ETLG included in the unique functional layer F21G of subpixel SP2 is covered with the protective layer 40 for covering the peripheral portion. Subpixel SP3 is provided on the protective layer 40. The peripheral portion of the protective layer is covered with the bottom electrode E1B of subpixel SP3. The layers included in the first functional layer F1B of subpixel SP3, the light emitting layer ELB and the layers included in the unique functional layer F21B are in contact with the protective layer 40 in the peripheral portions.

In the configuration of the modified example explained above, similarly, each of subpixels SP1, SP2 and SP3 constituting each pixel PX is provided so as to overlap a subpixel SP which is adjacent in the first direction X, and further, the peripheral portion of the bottom electrode E1 included in each subpixel SP is covered with the organic layer OR included in the subpixel SP. In this respect, the configuration of the modified example is not changed. Thus, the same effects as the effects explained above can be obtained.

In addition, in the configuration of the modified example, the protective layer 40 is provided between the bottom electrode of the subpixel SP provided on the upper side and the light emitting layer EL of the subpixel SP provided on the lower side. Thus, it is possible to further satisfactorily prevent one of the subpixels SP from emitting light in response to the light emission of the other subpixel SP in comparison with the configuration shown in FIG. 3 and FIG. 5B.

According to the embodiment explained above, the display device DSP comprises the following configuration. Each of subpixels SP1, SP2 and SP3 constituting each pixel PX is provided so as to overlap a subpixel SP which is adjacent in the first direction X, and further, the peripheral portion of the bottom electrode E1 included in each subpixel SP is covered with the organic layer OR included in the subpixel SP. This configuration can prevent the reduction in the light emission area in connection with high definition and realize the high definition of the display device.

The present embodiment shows the configuration in which only the common functional layer F22 included in the second functional layer F2 is provided as a common layer which is provided over a plurality of subpixels SP. However, the configuration is not limited to this example. All of the layers of the second functional layer F2 located on the upper side relative to the light emitting layer EL may be provided as common layers which are provided over a plurality of subpixels SP.

Further, the present embodiment shows the configuration in which subpixel SP1 is a red subpixel, and subpixel SP2 is a green subpixel, and subpixel SP3 is a blue subpixel. However, the configuration is not limited to this example. Subpixel SP1 may be a green subpixel, and subpixel SP2 may be a red subpixel, and subpixel SP3 may be a blue subpixel.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a base material; and
a display area including a plurality of pixels arrayed in matrix in a first direction and a second direction intersecting with the first direction, wherein
each of the pixels includes a first subpixel including an organic layer having a first color, a second subpixel including an organic layer having a second color and a third subpixel including an organic layer having a third color,
each of the subpixels comprises two overlap areas which overlap subpixels which are adjacent in the first direction, and an effective area which contributes display of images,
in the first subpixel, neither of the two overlap areas is included in the effective area,
in the second subpixel, one of the two overlap areas is included in the effective area, and the other one is not included in the effective area, and
in the third subpixel, both of the two overlap areas are included in the effective area.

2. The display device of claim 1, wherein
each of the subpixels includes bottom and top electrodes provided so as to interpose the organic layer between them,
the bottom electrode is connected to a pixel circuit for controlling driving of the subpixel, and
the top electrode is provided over a plurality of subpixels.

3. The display device of claim 2, wherein
a peripheral portion of the bottom electrode is covered with the organic layer and is not in contact with the top electrode.

4. The display device of claim 2, wherein
in the overlap area in which the first subpixel overlaps the second subpixel, the second subpixel is provided on an upper side relative to the first subpixel, and the bottom electrode included in the second subpixel reflects light emitted from the first subpixel such that the light does not contribute to display of images,
in the overlap area in which the second subpixel overlaps the third subpixel, the third subpixel is provided on an upper side relative to the second subpixel, and the bottom electrode included in the third subpixel reflects light emitted from the second subpixel such that the light does not contribute to display of images, and
in the overlap area in which the third subpixel overlaps the first subpixel, the third subpixel is provided on an upper side relative to the first subpixel, and the bottom electrode included in the third subpixel reflects light emitted from the first subpixel such that the light does not contribute to display of images.

5. The display device of claim 2, wherein
the organic layer included in each of the subpixels includes a light emitting layer corresponding to the color of the subpixel, and first and second functional layers provided so as to interpose the light emitting layer between them,
the first functional layer is provided between the bottom electrode and the light emitting layer and covers a peripheral portion of the bottom electrode, and
the second functional layer is provided between the light emitting layer and the top electrode and covers the light emitting layer.

6. The display device of claim 5, wherein
in the overlap area, between the bottom electrode included in the subpixel provided on the upper side and the light emitting layer included in the subpixel provided on the lower side, a carrier blocking layer is provided as the second functional layer of the subpixel provided on the lower side.

7. The display device of claim 6, wherein
the carrier blocking layer includes at least one of a hole blocking layer and an electron blocking layer.

8. The display device of claim 5, wherein
the second functional layer includes a common layer provided over the plurality of subpixels.

9. The display device of claim 5, wherein
in the overlap area, a protective layer is provided between the subpixel provided on the upper side and the subpixel provided on the lower side.

10. The display device of claim 9, wherein
the protective layer includes a carrier blocking layer or an insulating layer formed of an insulating material.

11. The display device of claim 1, wherein
the first color is red, and the second color is green, and the third color is blue.

12. The display device of claim 1, wherein
the first color is green, and the second color is red, and the third color is blue.
